(19) United States
(12) Patent Application Publication
(10) Pub. No.: US 2003/0151892 A1
(43) Pub. Date: Aug. 14, 2003

(54) Liquid cooling system with structure for liquid supply and electric device

(75) Inventors: Yuichi Kondo, Ebina (JP); Yasushi Neho, Atsugi (JP)

Correspondence Address: McDermott, Will & Emery, 600, 13th Street, N.W., Washington, DC, 20005-3096, US

(73) Assignee: HITACHI, LTD.

(21) Appl. No.: 10/359,570

(22) Filed: Feb. 7, 2003

(30) Foreign Application Priority Data
Feb. 8, 2002 (JP) 2002-032664

(51) Int. Cl. G06F 1/20; H05K 7/20

(52) U.S. Cl. 361/687; 361/699

(57) ABSTRACT

A liquid cooling system has a structure which permits easy filling, replenishment, or recovery of a cooling liquid for the system, and an electronic device incorporates such a liquid cooling system. The electronic device comprises a heat generating component. The cooling system comprises a jacket connected with the heat generating component, a heat sink, a circulation path through which the cooling liquid circulates between the jacket and the heat sink, and a pump which causes the cooling liquid to circulate through the circulation path. A reservoir tank or pipe incorporates an inner wall which divides the circulation path into two paths. A door enables opening and closing of the inner wall. An opening allows replenishments of the cooling liquid to one of the circulation paths divided in two.

### BACKGROUND

The subject matter relates to an electric device having a liquid cooling system which performs cooling with use of a cooling liquid. In particular, the subject matter is concerned with a tank structure for the replenishment of a cooling liquid, as well as an injector and an inhaler for a cooling liquid.

In a liquid cooling system for cooling with use of a cooling liquid, the cooling liquid is circulated through the interior of a metallic pipe by a pump installed within the system. The cooling liquid circulation causes heat exchange with a heat generating component such as a CPU, thereby cooling the heat generating component.

In the liquid cooling system there may occur a decrease of cooling liquid and consequent deficiency of the cooling liquid due to evaporation of the liquid or inclusion of gas into the liquid. This lowers the cooling ability. To suppress this phenomenon, a reservoir tank can be installed within the liquid cooling system. A reservoir tank is filled with the cooling liquid to replenish the cooling liquid accordingly to the decrease thereof in the liquid cooling system. Further, the reservoir tank is provided with a cooling liquid inlet, through which the cooling liquid is filled and replenished to the liquid cooling system.

If the pump itself of the liquid cooling system which uses a cooling liquid for cooling has a sufficient self-sucking ability, the cooling liquid can be filled throughout the entire liquid cooling system by activating the pump and allowing the cooling liquid to be sucked into the system. However, in a case of using a pump not having a sufficient self-sucking ability, it is necessary for an operator (or a user) to fill the cooling liquid throughout the liquid cooling system manually (or automatically).

In this case, there occurs problems such as spillage or dropping of the cooling liquid onto the system or adhering thereof to the operator's hands. Moreover, a difficulty is encountered in connecting work for connection to a joint portion or the like.

### SUMMARY

An electric device has a structure capable of easily filling, replenishing, or recovering a cooling liquid.

In one aspect, an electric device, comprises a heat generating component, a jacket which receives heat from the heat generating component, a heat sink which radiates the heat received in the jacket, and a circulation path through which a cooling liquid circulates between the jacket and the heat sink. A pump which causes the cooling liquid to circulate through the circulation path. An inner wall, for example in a reservoir tank or pipe, divides the circulation path into two paths. A door opens and closes the inner wall, and a replenishing opening enables replenishment of the cooling liquid to one of the bisected circulation paths.

In another aspect, an electric device comprises a heat generating component and a liquid cooling system for cooling the heat generating component. The liquid cooling system has a circulation path for circulating a cooling liquid through the system, and a pump which causes the cooling liquid to circulate through the circulation path. A separator separates the circulation path open-/close-wise into a first circulation path for the supply of the cooling liquid to the driver and a second circulation path which is supplied with the cooling liquid from the driver, and a first opening is provided in the first circulation path.

Additional objects, advantages and novel features of the examples will be set forth in part in the description which follows, and in part will become apparent to those skilled in the art upon examination of the following and the accompanying drawings or may be learned by production or operation of the examples. The objects and advantages of the inventive concepts may be realized and attained by means of the methodologies, instrumentalities and combinations particularly pointed out in the appended claims.

### BRIEF DESCRIPTION OF THE DRAWINGS

The drawing figures depict one or more implementations in accord with the present concepts, by way of example only, not by way of limitations. In the figures, like reference numerals refer to the same or similar elements.

FIG. 1 is a schematic diagram of a personal computer with a liquid cooling system installed therein, the liquid cooling system using a cooling liquid for cooling.

FIG. 2 is a cross sectional view of an example of a reservoir tank.

FIG. 3 is across sectional view of an example of the reservoir tank which is in a state of filling the liquid cooling system with the cooling liquid.

FIG. 4 is a diagram showing another example of a separator.

FIG. 5 is a diagram showing the reservoir tank and an example of an injector and an inhaler for a cooling liquid.

FIG. 6 is a diagram showing an example of a reservoir tank and an example of a injector for a cooling liquid.

### DETAILED DESCRIPTION

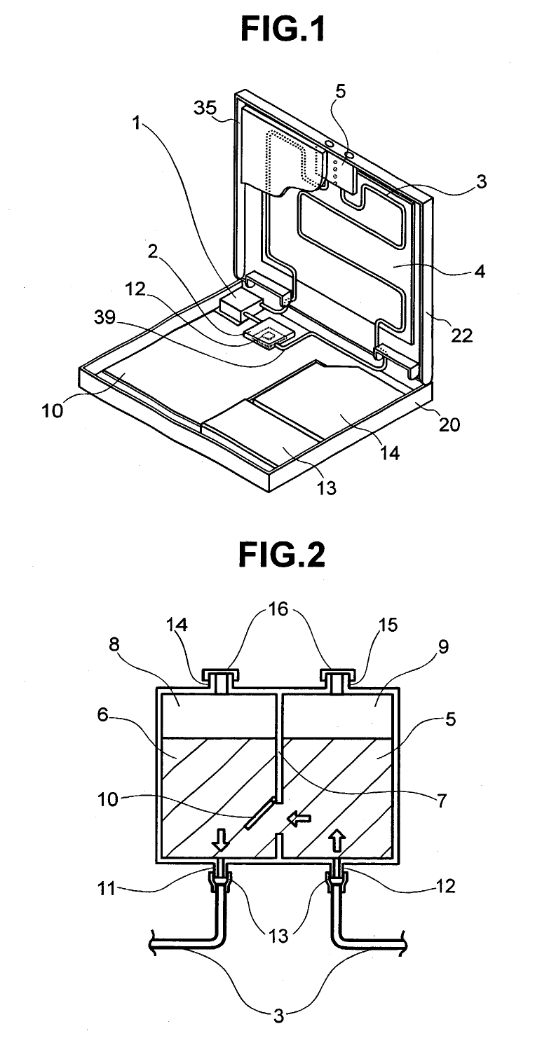

An electric device embodying the cooling system will be described hereinunder with reference to FIGS. 1 to 6. Tautological explanations will be omitted.

A description will be made of a notebook type personal computer (PC) as an example of the electric device, although those skilled in the art will recognize that the cooling system is applicable other types of electronic devices. FIG. 1 is a schematic diagram of a PC with a liquid cooling system installed therein, the liquid cooling system using a cooling liquid for cooling.

The PC in FIG. 1 has two enclosures, a body case 20 as a first enclosure and a display case 22 as a second enclosure. In the body case 20 are accommodated a mother board 10, a CPU (central processing unit) 12 mounted on the mother board, a hard disk drive (HDD) 13, and a CD-ROM drive 14. The CPU 12 will be referred to as a heat generating component, but the HDD 13 may be referred to as a heat generating component.

A pump 1 and a water cooling jacket 2 both used in a liquid cooling system are also installed in the body case 20, which cooling system will be described later. For the convenience of explanation, FIG. 1 shows a removed state of a keyboard (not shown) which is usually installed on an upper surface of the body case 20.

The display case 22 incorporates a liquid crystal display unit 15 therein. Moreover, a metallic pipe 3, a heat sink 4, and a reservoir tank 5 as components of the liquid cooling system to be described later are contained in the display case 22. These components of the liquid cooling system are arranged on an outer side opposite to a display surface which comes into opposition to the keyboard when the PC is folded.

Thus, the liquid cooling system is provided with the pump 1, water cooling jacket 2, metallic pipe 3, heat sink 4, and reservoir tank 5. The pump 1 serves as a driver which circulates a cooling liquid through the whole of the liquid cooling system. The water cooling jacket 2 is internally formed with a path for the circulation of the cooling liquid. The water cooling jacket 2 is installed in abutment against the CPU 12.

Within the metallic pipe 3 is also formed a cooling liquid circulation path. The metallic pipe 3 includes part of a cooling liquid circulation path formed within the display case 22. The metallic pipe 3 is in contact with the heat sink 4 to transfer heat to the heat sink 4. Further, the metallic pipe 3 is connected to the reservoir tank 5 to let the cooling liquid flow into and out of the tank 5. As a result of circulation of the metallic pipe 3 and the cooling liquid through the components it is possible to cool the heat generating component.

A “sink” is a device or place for disposing of energy, in this case, heat collected from the electronic device. In the example, the heat sink 4 receives heat from the cooling liquid and radiates the heat to the exterior. More specifically, the heat is radiated from the heat sink 4 to the exterior through the display case 22. A metallic plate for example is used as the heat sink 4. Although the heat sink 4 and the metallic pipe 3 are formed separately, a part of the metallic pipe 3 may be rendered integral with a case of the heat sink 4 and the display.

The reservoir tank 5 is a cooling liquid storing vessel for replenishing the cooling liquid to the whole of the liquid cooling system. An inner wall having a valve is provided in the interior of the reservoir tank 5. With use of the valve, the cooling liquid can be poured into the liquid cooling system.

As shown in FIG. 1, the reservoir tank 5 is installed in an upper portion of the case 22, taking into account the case where air gets into the liquid cooling system as a result of evaporation of the cooling liquid from the entire system. That is, to decrease the amount of air mixing into the pump 1 even in case of air being present inside of the cooling system, the reservoir tank 5 may be used as an air reservoir, too. With this point in mind, the cooling tank 5 is disposed so as to assume an upper location in a normal operating position. The following description will be given with the vertical direction as a reference in the arrangement of the display case shown in FIG. 1.

At least one tube 39 is used to connect components in the cooling system which are arranged within the body case 20. The tube provides a connection among the pump 1, water cooling jacket 2, and metallic pipe 3 laid within the display case 22. The tube is internally formed with part of the circulation path also, through which the cooling liquid circulates.

When the liquid cooling system operates, the cooling liquid discharged by the pump 1 passes through the water cooling jacket 2 which is installed on the CPU 12. The water cooling jacket 2 receives heat from its own surface abutted against the CPU 12 and transfers it to the cooling liquid which is circulating through the water cooling jacket 2. The cooling liquid passes through the tube disposed within the PC body case 20 and flows through the metallic pipe 3. The heat of the cooling liquid transfers from the metallic pipe 3 to the heat sink 4, from which it is then dissipated to the outside air. The cooling liquid thus cooled returns to the pump 1 and again flows through the liquid cooling system along the path. By repeating these steps the cooling liquid cools the heat generating component constantly. Pure water (fresh water) or antifreeze is used as the cooling liquid 6, although those skilled in the art will recognize that the system may utilize other types of coolant.

FIG. 2 illustrates a sectional structure of the reservoir tank 5. The reservoir tank 5 shown in FIG. 2 is with the liquid cooling system operating.

The reservoir tank 5 has an inner wall 7. The inner wall 7 partitions the reservoir tank 5 into a left chamber 8 and a right chamber 9. The inner wall 7 is provided with a valve 10. Further, the reservoir tank 5 has an outlet port 11 and an inlet port 12. The tank 5 has a first opening 14 and a second opening 15.

As noted above, the inner wall 7 and the valve 10 serve as a separator to divide the reservoir tank 5 into two chambers 8 and 9. With the separator, the circulation path in the liquid cooling system is divided in two. Assume that the path reins from flowing of the cooling liquid out of a discharge port of the pump 1 until flowing of the cooling liquid into a suction port of the pump 1 is the circulation path. Then, the path is divided into a first circulation path from the chamber 8 up to the suction port of the pump 1 and a second circulation path from the discharge port of the pump 1 up to the chamber 9. Thus, the separator divides the circulation path into two.

The interior of the reservoir tank 5 may be divided in two by the inner wall 7. One chamber 8 is formed with the outlet port 11 and the first opening 14, and the another chamber 9 is formed with the inlet port 12 and the second opening 15. In FIG. 2, the outlet port 11 and the inlet port 12 are provided in lower positions of the reservoir tank 5, while the first and second openings 14, 15 are provided in upper positions of the reservoir tank 5. However, no limitation is made thereto. These ports and openings may be provided in side faces of the tank insofar as the interior of the tank 5 is divided horizontally in the manner described above. Incidentally, when the direction of air discharge and a pressure difference between the two chambers 8 and 9, which will be described later, are taken into account, it is preferable to dispose the ports 11, 12 and openings 14, 15 to permit the chambers to be separated in the vertical direction.

The valve 10 is an opening/closing valve used to open or close the inner wall. The valve is an example of a door between the two chambers 8 and 9. The chambers 8, 9 defined in the interior of the reservoir tank 5 are connected with each other through the valve 10. With the valve 10 closed, the chambers 8 and 9 are isolated from each other, while upon opening of the valve 10, both chambers 8 and 9 are put in communication with each other. The valve 10 in FIG. 2 is not given any forcible urging force in its opening and closing directions.

The state free of any forcible urging force will herein be referred to as “a closed state.” The opening/closing operation is performed in accordance with a pressure difference between the chambers 8 and 9. When the pressure of the chamber 8 is higher beyond a certain level than that of the chamber 9, the valve closes.

The outlet port 11 is connected to the metallic pipe 3 through a connecting tube. The cooling liquid 6 contained in the reservoir tank 5 flows out from the outlet port 11 into the metallic pipe 3. Likewise, the inlet port 12 is connected to the metallic pipe 3. The cooling liquid 6 flows into the reservoir tank 5 from the metallic pipe 3 through the inlet port 12. Thus, in the interior of the reservoir tank 5, the cooling liquid flows through the chamber 9 from the inlet port 12, then passes the valve 10, flows into the chamber 8, and further flows out of the outlet port 11 from the tank 5.

When the liquid cooling system is in operation, as shown in FIG. 2, and if the discharge port and suction port of the pump are assumed to be most upstream and most downstream sides respectively, the pressure of the chamber 9 positioned upstream is higher than that of the chamber 8 because of the pump's power. And the valve 10 is open and the cooling liquid flows into the chamber 8 from the chamber 9.

The first opening 14 serves as a cooling liquid replenishing port. A container to contain the cooling liquid, e.g., a syringe, is brought into close contact with the first opening 14. The cooling liquid is replenished under the application of pressure. The second opening 15 serves as a gas discharger for the air from the interior of the liquid cooling system during injection of the cooling liquid. When the liquid cooling system is in operation, the openings 14 and 15 are each closed with a cap 16.

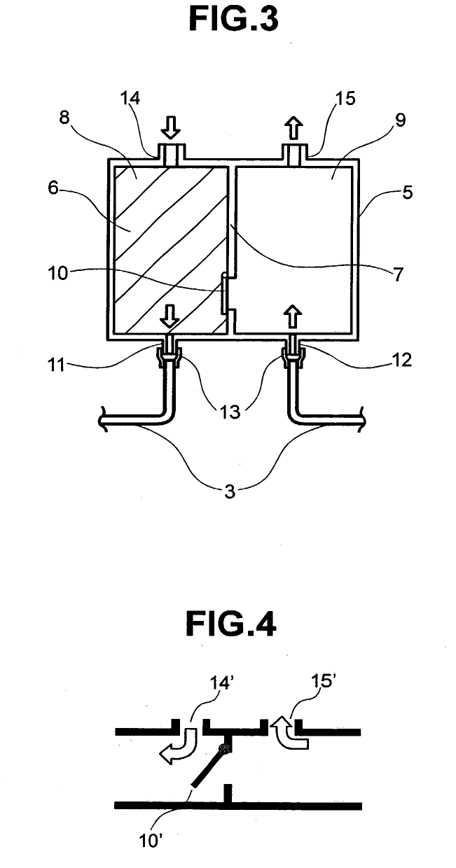

The following description is now provided about processing for the fill of cooling liquid into the liquid cooling system. FIG. 3 shows a section of the reservoir tank 5 in a filling state of the cooling liquid 6 into the liquid cooling system. A difference from FIG. 2 resides in that the valve 10 is closed. The filling of cooling liquid is performed in an OFF condition of the liquid cooling system.

In a state before the fill the valve 10 is not closed. In this state, the cooling liquid 6 is injected into the chamber 8 while a cooling liquid injector such as a syringe containing the cooling liquid is put in close contact with the opening 14. When the cooling liquid is charged into the chamber 8 up to the height of the valve 8, it flows into the chamber 9 because the valve 10 is not closed. If the cooling liquid 6 is further injected at its level higher than the valve 10, the volume of the cooling liquid in the chamber 8 increases temporarily and the internal pressure of the same chamber increases and becomes higher than that of the chamber 9. When this pressure difference becomes higher than a predetermined condition, the valve 10 is closed with the pressure of the cooling liquid 6. Upon closure of the valve 10 the cooling liquid 6 no longer enters the chamber 9.

If the cooling liquid is further injected in the closed state of the valve 10, the air present within the chamber 8 is forced out of the outlet port 11 into the metallic pipe 3 and the interior of the chamber 8 is filled with cooling liquid, assuming such a state as shown in FIG. 3. Upon further injection of the cooling liquid, the liquid flows into the circulation path including the interior of the metallic pipe 3, pump 1, and cooling jacket 2. The air present within those components flows from the inlet port 12 into the chamber 9 and is forced out from the opening 15. In this way the cooling liquid reaches the chamber 9. When the cooling liquid 6 is filled up to above the valve 10, the valve opens under the pressure of the cooling liquid, thus permitting circulation of the liquid. With the liquid cooling system ON, the valve 10 is opened by the pressure of the cooling liquid 6, allowing the cooling liquid to flow from the chamber 9 to the chamber 8. Thus, the degree of fill of the cooling liquid in the liquid cooling system can be adjusted by adjusting the height of the valve 10 in the cooling tank 5.

According to the configuration described above, the interior of the reservoir tank 5 can be divided in two at the time of injection of the cooling liquid. In this configuration, if the cooling liquid 6 is injected while preventing the escape of air from the opening 14, it is possible to effect the filling of the cooling liquid while forcing out the air present in the interior of the liquid cooling system into the chamber 9.

Besides, since the opening 14 for the replenishment of cooling liquid is disposed in the downstream-side circulation path out of the bisected circulation paths, the interior of the liquid cooling system can be filled with the cooling liquid in a successive manner. Moreover, since the opening 15 for the discharge of air is disposed in the upstream-side circulation path out of the bisected circulation path, it is easy to discharge air and hence it is possible to reduce the pressure for the fill of cooling liquid.

Further, according to the construction being considered, the valve 10 is closed in accordance with the level of pressure in the opening for replenishment and therefore the filling of the cooling liquid 6 can be done even without activating the pump 1 by the supply of electricity thereto. That is, the filling of cooling liquid can be effected by the pressurizing force of the liquid injector and by the action of the valve even without relying strongly on the self-sucking ability of the pump.

Although in the reservoir tank 5 an inner wall 7 is provided as a separator within the reservoir tank 5, this constitutes no limitation. An inner wall 7 may be formed in another circulation path. FIG. 4 shows an example thereof. In the example shown in FIG. 4, a metallic pipe is formed with openings 14′ and 15′ and a valve 10′ is provided between both openings. Thus, at one portion of the circulation path there is provided a separator which separates the circulation path into two and opens or closes the separated paths. The valve 10′ may be substituted by another opening/closing door.

Although in connection with the example shown in FIG. 3 reference is about to the case where the filling of cooling liquid is performed in an empty condition of the reservoir tank 5, the operations as above may be done also in a case of replenishing the cooling liquid in the presence of a certain amount of cooling liquid. Further, the injection of cooling liquid is performed in a closely contacted state of both the opening 14 and the liquid injector, there is made no limitation thereto. In the case where both are not completely brought into close contact, the pressure into the chamber 8 is difficult to rise, but if the differential pressure for closing the valve is set small, the injection of cooling liquid can be effected even in such a state.

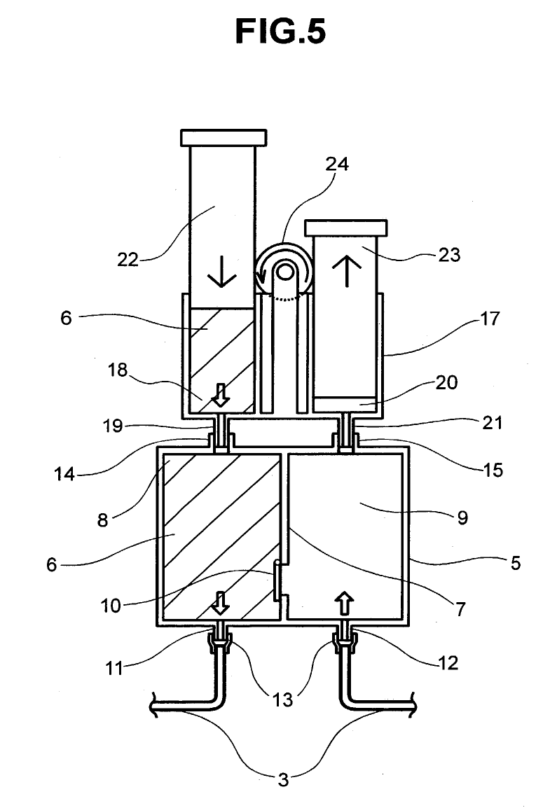

Referring now to FIG. 5, there is illustrated an injector and an inhaler for a cooling liquid. FIG. 5 is a sectional view of a device 17 for the fill and recovery of cooling liquid to and from the liquid cooling system provided with the reservoir tank 5 which is shown in FIG. 2. An injection port 19 of an injecting portion 18 in the device 17 is connected to the opening 14 of the chamber 8, while a suction port 21 of a suction portion 20 is connected to the opening 15 of the chamber 9.

The device 17 is an injector and an inhaler. The injector comprises an injection piston 22, the injecting portion 18 provided with the injection port 19. The inhaler comprises a suction piston 23, the suction portion 20 provided with the suction port 21. A connecting portion 24 which connects the injection piston 22 and the suction piston 23 with each other for drive.

First, in the case of filling the cooling liquid 6 into the liquid cooling system, the cooling liquid is charged beforehand into the injecting portion 18. The injection piston 22 provided in the injecting portion 18 and the suction piston 23 provided in the suction portion 20 are connected together movably by the connecting portion 24. By pushing the injection piston 22 automatically or manually, pressure is applied to the injecting portion 18, permitting injection of the cooling liquid 6. The suction piston 23 connected to the injection piston 22 operates to suck in air from the interior of the liquid cooling system into the suction portion 20.

For the recovery of cooling liquid from the liquid cooling system, air is charged beforehand into the injecting portion 18. By pushing the injection piston 22, pressure is applied to the injecting portion 18 for the injection of air and the suction piston 23 connected to the injection piston 22 operates, permitting the cooling liquid 6 to be sucked (recovered) into the suction portion 20 of the device 17 from the interior of the liquid cooling system. The reservoir tank 5 assumes the state explained above in connection with FIG. 3.

With use of the device 17, by performing the injection of cooling liquid (or air) and the suction of air (or cooling liquid) from the interior of the liquid cooling system, it is possible to easily effect the filling or recovery of the cooling liquid 6 to or from the liquid cooling system.

Although in the example above the description is about the filling or recovery of cooling liquid, this constitutes no limitation. The structure of the liquid cooling system in FIG. 5 is also applicable to the replenishment of cooling liquid.

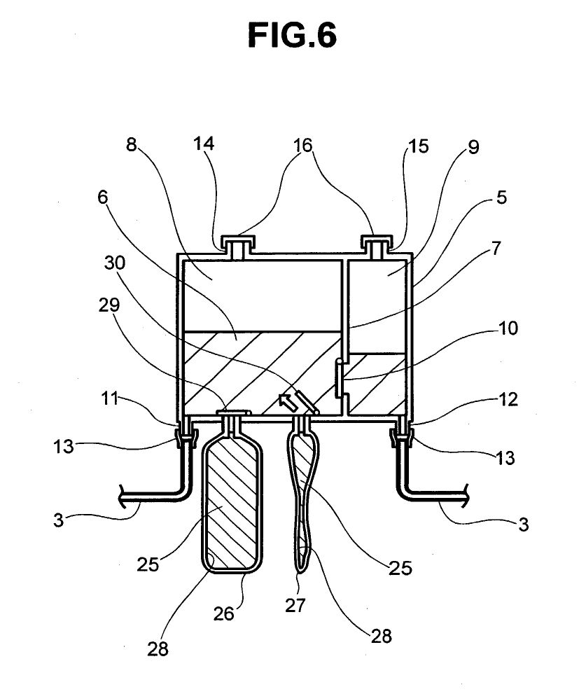

Referring now to FIG. 6, there is illustrated a cooling liquid replenishing structure. In this structure, by using a transparent material as the material of the reservoir tank 5, it becomes possible to visually check a residual amount of the cooling liquid and both maintainability and workability can be improved. In this case, if the material is glass or the like, machining is difficult and cost increases. A plastic material is most suitable. With the plastic material, however, there arises the problem that the amount of moisture evaporated is larger than that of metal.

According to the cooling liquid replenishing structure, a tube formed of a material which is smaller in the amount of moisture evaporated than the plastic material is filled with a cooling liquid for replenishment, thereby permitting replenishment of the cooling liquid.

In FIG. 6, fill tubes 26 and 27 each containing a cooling liquid 25 for replenishment are provided on the lower side of a reservoir tank 5. Although two tubes are shown, even a single tube suffices if it is of a large capacity. Although the tube 27 shown in FIG. 6 is deflated, this is because the tube 27 is in a state after the replenishment of cooling liquid; in other words, it is initially filled with cooling liquid.

The interiors of the tubes 26 and 27 are formed of a material 28 which is small in the amount of moisture evaporated, such as aluminum. The tubes 26 and 27 are connected to the reservoir tank 5 through valves 29 and 30, respectively. When the cooling liquid replenishing structure is not in use, the valves 29 and 30 are closed like the valve 29 in the figure by virtue of the pressure of the cooling liquid 6 in the reservoir tank 5.

When the cooling liquid 25 for replenishment from the tubes 26 and 27 is injected (replenished) into the reservoir tank 5, the tubes 26 and 27 are squeezed like the tube 27 in FIG. 6 to inject (replenish) the cooling liquid 25 for replenishment into the chamber 8 of the reservoir tank 5. The valves 29 and 30 become open like the valve 30, thereby permitting the injection (replenishment). When the injection (replenishment) is over, the valves 29 and 30 close like the valve 29 by virtue of the pressure of the cooling liquid 6 to prevent back-flow of the cooling liquid 6 into the tubes 26 and 27. The reservoir tank 5 is in the state explained above in connection with FIG. 3.

With such a cooling liquid replenishing structure, it is easy for the user or the operator to replenish the cooling liquid 6 the amount of which has been decreased due to a long-term use of the electronic device with the liquid cooling system mounted thereon. In more particular terms, if there is adopted the configuration wherein the interior of the reservoir tank is partitioned into chambers so that the chambers are isolated from each other with use of a valve, then when air gets into the cooling liquid circulation path for some reason or other, the cooling liquid can be fed under pressure to the pump inlet side. Besides, it is possible to obviate the phenomenon in which a pump not having a self-sucking ability races and the cooling liquid does not circulate.

Although the reservoir tank 5 for the liquid-cooled PC is fixed integrally with the device in which the liquid cooling system is installed, the reservoir tank 5 may be constructed as a cartridge type for easier attachment and detachment (i.e., replacement) to and from the device, thereby permitting the user to replenish the cooling liquid 6 easily.

As set forth above, the features of the above embodiments bring about the following configurations, functions and effects. The interior of the reservoir tank is partitioned with a valve into chambers and the chambers are connected to each other through a valve to facilitate filling and replenishment of the cooling liquid. In the cooling liquid filling device, the injecting portion and the suction portion are connected with each other to perform both injection and suction simultaneously, thereby permitting the liquid cooling system provided with the reservoir tank to effect the filling and recovery of cooling liquid easily.

Moreover, the reservoir tank is provided on the lower side thereof with a cooling liquid injector having tubes for the storage of cooling liquid for replenishment, the tubes being formed of a material which is smaller in the amount of moisture evaporated than the material of the reservoir tank, whereby the user can replenish the cooling liquid easily.

Since the interior of the reservoir tank is partitioned into chambers and the chambers are connected to each other through a valve, the filling and replenishment of cooling liquid to the liquid cooling system can be done easily.

Moreover, by using the cooling liquid fill and recovery device, the cooling liquid can be filled and recovered easily for the liquid cooling system.

Further, by providing the reservoir tank with the cooling liquid injector, the user or the worker can easily replenish the cooling liquid to the device with the liquid cooling system mounted thereon.

While the foregoing has described what are considered to be the best mode and/or other examples, it is understood that various modifications may be made therein and that the invention or inventions disclosed herein may be implemented in various forms and examples, and that they may be applied in numerous applications, only some of which have been described herein. It is intended by the following claims to claim any and all modifications and variations that fall within the true scope of the inventive concepts.

1. An electric device having a liquid cooling system, comprising:
a heat generating component;
a jacket abutted against the heat generating component;
a heat sink for radiating the heat of a cooling liquid;
a driver which causes a cooling liquid flowing;
a circulation path which enables a cooling liquid flow from the driver and through the jacket and the heat sink and to the driver;
an inner wall located to divide the circulation path into a first divided path and a second divided path;
a door on the inner wall; and
a replenishing port on the circulation path.

2. An electric device according to claim 1, wherein
the door comprises an opening/closing valve.

3. An electric device according to claim 2, wherein
the replenishing port is on the first divided path, and the opening/closing valve is opened and closed with pressure exerted from the first divided path.

4. An electric device according to claim 1, wherein
the first divided path is an upstream side in a cooling liquid flowing direction,
the second divided path is a downstream side in the cooling liquid flowing direction, and
the replenishing port is on the first divided path.

5. An electric device according to claim 4, wherein
the circulation path has a tank, the inner wall divides that tank, a first part of the tank belongs to the first divided path, and second part of the tank belongs to the second divided path.

6. An electric device according to claim 5, wherein
the replenishing port is formed on the first part of the tank.

7. An electric device according to claim 5, further comprising:
a first case which contains at least the heat generating component and the jacket; and
a second case which contains at least the tank.

8. An electric device according to claim 7, further comprising a display unit incorporated in the second case.

9. An electric device according to claim 1, wherein
the heat generating component is a CPU.

10. An electric device according to claim 4, further comprising
a gas discharger formed in the second divided path.

11. An electric device according to claim 1, wherein
the electric device is a computer.

12. An electric device comprising:
a heat generating component; and
a liquid cooling system for cooling the heat generating component,
the liquid cooling system comprising:
a circulation path though which a cooling liquid passes;
a pump which causes the cooling liquid to circulate through the circulation path;
a separator located to separate the circulation path into a first separated path for the supply of the cooling liquid to the pump and a second separated path which is supplied with the cooling liquid from the pump; and
a first opening on the first separated path.

13. An electric device according to claim 12, wherein
the separator comprises an opening/closing valve which is opened or closed in accordance with a pressure difference between the first and second separated paths.

14. An electric device according to claim 13, wherein
the opening/closing valve closes when the pressure of the first separated path is higher than the pressure of the second separated path.

15. An electric device according to claim 12, wherein
the circulation path has a reservoir tank, and
the separator is disposed within the reservoir tank.

16. An electric device according to claim 15, wherein
the reservoir tank has an inlet port for inflow of the cooling liquid and an outlet port for outflow of the cooling liquid, and
the separator comprises an inner wall located to separate the first separated path with the outlet port and the second separated path with the inlet port.

17. An electric device according to claim 15, wherein
the first opening is provided in the reservoir tank.

18. An electric device according to claim 15, further comprising:
a first case which contains at least the heat generating component; and
a second case which contains at least the reservoir tank.

19. An electric device according to claim 18, wherein
the reservoir tank is disposed in an upper position in the interior of the second case, and
the first opening is formed in an upper position of the reservoir tank.

20. An electric device according to claim 12, further comprising
a second opening provided in the second separated path.

21. An electric device according to claim 20, further comprising:
an injector in contact with the first opening; and
a inhaler in contact with the second opening.

22. An electric device according to claim 16, further comprising:
a fill tube connected with the first separated path having the outlet port and which contains a cooling liquid.

23. An electric device according to claim 12, wherein
the electric device is a computer.

24. A liquid cooling system having a cooling liquid filling mechanism, comprising:
a jacket for receiving heat from an electronic component;
a circulation path through which a cooling liquid flows;
a pump which feeds the cooling liquid to the jacket through the circulation path;
a separator located to separate the circulation path into a first separated path for the supply of the cooling liquid to the pump and a second separated path which is supplied with the cooling liquid from the pump; and
a first opening provided in the first separated path.

25. A liquid cooling system according to claim 24, wherein
the separator is an opening/closing valve which is opened or closed in accordance with a pressure difference between the first and second separated paths.

26. A liquid cooling system according to claim 25, wherein
the opening/closing valve closes when a pressure of the first separated path is higher than a pressure of the second separated path.

27. A liquid cooling system according to claim 24, wherein
the circulation path has a reservoir tank, and
the separator is installed within the reservoir tank.

28. A liquid cooling system according to claim 27, wherein
the reservoir tank has an inlet port for inflow of the cooling liquid and an outlet port for outflow of the cooling liquid, and
the separator is an inner wall located to separate the first separated path with the outlet port and the second separated path with the inlet port.

29. A liquid cooling system according to claim 26, wherein
the first opening is provided in the reservoir tank.

30. A liquid cooling system according to claim 24, further comprising
a second opening provided in the second circulation path.

31. A liquid cooling system according to claim 30, further comprising:
an injector in contact with the first opening; and
a inhaler in contact with the second opening.

32. A liquid cooling system according to claim 28, further comprising
a fill tube connected with the first separated path and which contains a cooling liquid.

33. A liquid cooling system for cooling an electronic computer with use of liquid as a coolant within the computer, comprising:
a reservoir tank whose interior is partitioned into chambers; and
an opening/closing valve for isolating or communicating the partitioned chambers from or with each other.

34. A liquid cooling system according to claim 33, further comprising a tube filled with a cooling liquid for replenishment, the tube being attached to one of the partitioned chambers;
wherein when the tube is subjected to a squeezing operation, the cooling liquid for replenishment contained therein can be brought into communication with the one chamber.

35. A liquid cooling system according to claim 34, wherein
the tube is formed of a material such that less coolant evaporates from the tube than evaporates from the reservoir tank.

36. A device for replenishment of cooling liquid to an cooling liquid system comprising a first circulation path and second circulation path for cooling liquid, the device comprising:
a injecting portion comprising:
a supply contained a cooling liquid,
an injection port for fitting the supply to a first opening provided on the first circulation path of the cooling liquid system, and
an injection piston for pushing the cooling liquid through the injection port,
a sucking portion comprising:
a suction piston linked to the injection piston, and
a suction port for fitting the suction piston to a second opening provided on the second circulation path of the cooling liquid system,
a driver connecting the injection piston and the suction piston with each other for drive.

37. A method for filling a cooling liquid to a liquid cooling system, which comprising a cooling liquid path divided into a first and second circulation path, and a door located between the first and the second circulation paths; the method comprising the steps of:
injecting the cooling liquid into the first circulation path;
closing the door;
flowing an air in the first circulation path to the second circulation path;
forcing the air out of the second circulation path; and
filling the cooling liquid into the second circulation path.
